(19) United States
(12) Patent Application Publication
(10) Pub. No.: US 2019/0035621 A1
(43) Pub. Date: Jan. 31, 2019

(54) SHAPED CIRCUIT WAFERS

(71) Applicant: QUALCOMM Incorporated, San Diego, CA (US)

(72) Inventors: Changhan Hobie YUN, San Diego, CA (US); Mario Francisco VELEZ, San Diego, CA (US); David Francis BERDY, San Diego, CA (US); Chengjie ZUO, San Diego, CA (US); Jonghae KIM, San Diego, CA (US); Niranjan Sunil MUDAKATTE, San Diego, CA (US); Xiaoju YU, San Diego, CA (US)

(21) Appl. No.: 15/659,591

(22) Filed: Jul. 25, 2017

(51) Int. Cl. H01L 21/02; H01L 21/67; H01L 23/15; H01L 21/20

(52) U.S. Cl. CPC H01L 21/02035; H01L 21/67; H01L 21/2007; H01L 21/02422; H01L 23/15

(57) ABSTRACT

To overcome the deficiencies of conventional rectangular circuit wafers, a glass substrate circuit wafer with an obtuse angle on the perimeter may be used. In one example, a glass substrate wafer may include a first circuit on a first portion of a glass substrate and a second circuit on a second portion of the glass substrate where the first portion has a first obtuse angle and the second portion has a second obtuse angle that is complementary to the first obtuse angle on the perimeter of the first portion to mate together to form an outer perimeter that comprises right angles.

### FIELD OF DISCLOSURE

This disclosure relates generally to wafers, and more specifically, but not exclusively, to shaped glass wafers with circuits or passive components.

### BACKGROUND

A semiconductor device may contain active and passive electrical structures. Active structures, including bipolar and field effect transistors, control the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions. Semiconductor devices are generally manufactured using two complex manufacturing processes, i.e., front-end manufacturing, and back-end manufacturing, each involving potentially hundreds of steps. Front-end manufacturing involves the formation of a plurality of circuits on the surface of a semiconductor wafer. Each circuit is typically identical. Back-end manufacturing involves singulating individual circuits from the finished wafer and packaging the circuit to provide structural support and environmental isolation to form a semiconductor device. One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller semiconductor device size can be achieved by improvements in the front-end process resulting in semiconductor devices with smaller, higher density active and passive components. Back-end processes may result in semiconductor device packages with a smaller footprint by improvements in electrical interconnection and packaging materials.

In the dicing process, a thin circular blade, often called the dicing blade, is used in the dicing process to cut the circuits into rectangular wafers with vertical and horizontal cuts. Thus, circuits are formed on a wafer and the wafer is cut using rectangular dicing to separate each circuit onto its own wafer. Since different circuits have different components, their respective circuit wafers are of different sizes. For example, inductor sizes in filters are different for optimized performance, and the cut wafers for each different sized inductor are of a different size with unnecessary waste die area due to the rectangular dicing. Glass wafers or substrates in semiconductor applications are known to provide many advantages over other wafer materials. These advantages include, for example, high resistivity and low radio frequency (RF) coupling to devices. Also, during manufacturing processes, glass wafers do not heat up as much as other types of wafers and, hence do not succumb to a degraded quality factor to the extent of other wafer materials. However, glass wafers must be singulated with precise control to avoid damaging the wafer through chipping or cracking. Therefore, glass wafers generally are not singulated with lasers or similar devices.

Accordingly, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a glass substrate wafer comprises: a first circuit on a first portion of a glass substrate; a second circuit on a second portion of the glass substrate; and wherein the first portion has a first obtuse angle on a perimeter of the first portion and the second portion has a second obtuse angle on a perimeter of the second portion that is complementary to the first obtuse angle on the perimeter of the first portion and the first portion and the second portion are configured to mate together to form an outer perimeter that comprises right angles.

In another aspect, a package comprises: a passive-on-glass (POG) structure with a passive component; and wherein the POG structure has a substrate that comprises an obtuse interior angle, a reflex interior angle, and a plurality of right angles.

In still another aspect, a method of dicing a semiconductor wafer, comprises: forming a first circuit on a wafer; forming a second circuit on the wafer; and dicing the wafer to separate the first circuit from the second circuit, wherein the diced first circuit has a perimeter with a first obtuse angle and the diced second circuit has a perimeter with a second obtuse angle that is complementary to the first obtuse angle such that the first circuit and the second circuit are configured to mate together to form an outer perimeter that comprises right angles.

In still another aspect, a glass substrate wafer comprises: a first circuit on a first portion of a glass substrate; a second circuit on a second portion of the glass substrate; and wherein the first portion has an obtuse angle on a perimeter of the first portion and the second portion has a reflex angle on a perimeter of the second portion that is complementary to the obtuse angle on the perimeter of the first portion.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary diplexer circuit for an antenna in accordance with some examples of the disclosure.

FIG. 2 illustrates an exemplary wafer with a low pass filter circuit in accordance with some examples of the disclosure.

FIG. 3 illustrates an exemplary wafer with a high pass filter in accordance with some examples of the disclosure.

FIG. 4A illustrates two exemplary mated wafers in accordance with some examples of the disclosure.

FIG. 4B illustrates four exemplary mated wafers in accordance with some examples of the disclosure.

FIG. 4C illustrates four exemplary mated wafers in accordance with some examples of the disclosure.

FIG. 4D illustrates two exemplary wafers and an antenna in accordance with some examples of the disclosure.

FIG. 5 illustrates an exemplary partial method for dicing a wafer in accordance with some examples of the disclosure.

FIG. 6 illustrates various electronic devices that may be integrated with any of the aforementioned integrated device, semiconductor device, integrated circuit, die, interposer, package or package-on-package (PoP) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs. For example, using obtuse angle dicing to cut out the unused die area of a circuit wafer instead of conventional rectangular dicing will lessen the footprint of the cut wafer and cut away area may be used for the next neighboring die to lessen the footprint on a printed circuit board for both die wafers. Thus, obtuse angle dicing of approximately 135 degrees may result in a die wafer size reduction of 20% (increasing the number of dies per wafer) and a printed circuit board area reduction of 40% for combined diplexer applications. Furthermore, the footprint on a printed circuit board for a diplexer surrounding a via or antenna port may be reduced and also result in improved path loss of approximately 5 dB per centimeter of signal path reduction between the diplexer and the antenna port.

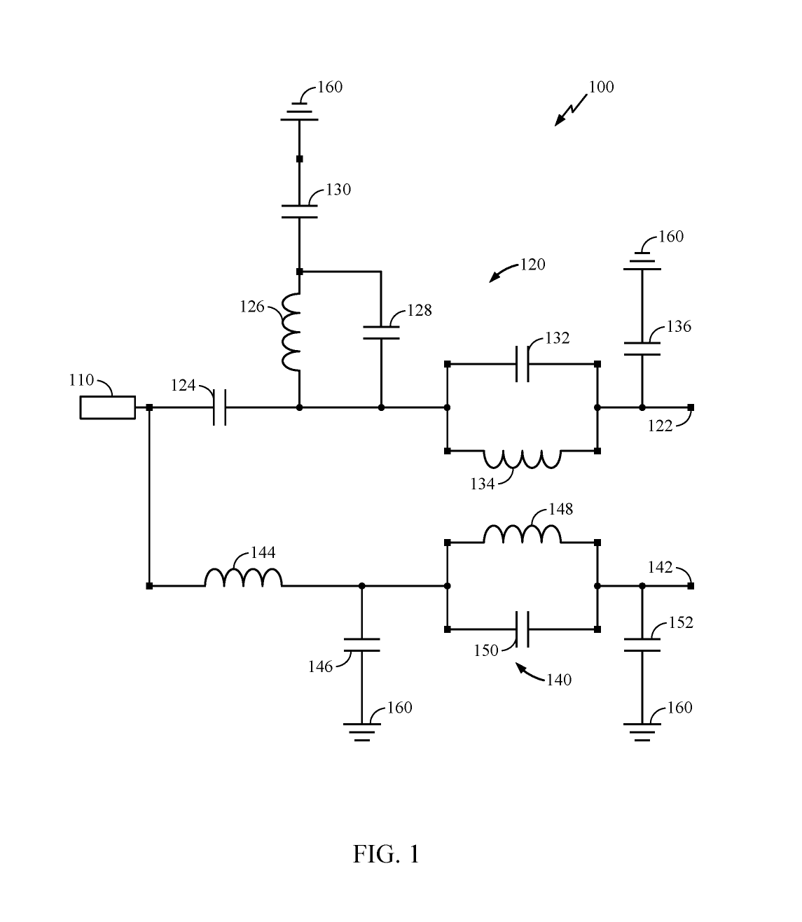

FIG. 1 illustrates an exemplary diplexer circuit for an antenna in accordance with some examples of the disclosure. As shown in FIG. 1, a diplexer circuit 100 (e.g., a passive on glass structure with a passive component) may include an antenna 110 (e.g., a WiFi or Cellular antenna) coupled to a high pass filter 120 and a low pass filter 140 to filter the antenna 110 signal at the appropriate frequency range. For example, a cellular antenna 110 may include a high pass filter 120 configured to filter the antenna 110 signal between 1710 to 2690 MHz and a low pass filter 140 configured to filter the antenna 110 signal between 699 to 960 MHz. The high pass filter 120 may include an output 122, a first capacitor 124 coupled to the antenna 110, a first inductor 126 in parallel with a second capacitor 128, a third capacitor 130 coupled to a ground 160, a fourth capacitor 132 in parallel with a second inductor 134, and a fifth capacitor 136. The low pass filter 140 may include an output 142, a first inductor 144 coupled to the antenna 110, a first capacitor 146 coupled to a ground 160, a second inductor 148 in parallel with a second capacitor 150, and a third capacitor 152 coupled to a ground 160. The inductors and capacitors for the high pass filter 120 may be different sized from each other and from the inductors and capacitors for the low pass filter 140 to optimize the performance of the diplexer circuit 100 as well as using different metal stacks and dielectric material due to the frequency band goals. For example, the first inductor 144 of the low pass filter 140 may be a high, wide copper inductor and the first capacitor 146 of the low pass filter 140 may be a high density capacitor (low K) whereas the first capacitor 124 of the high pass filter 120 may be a low density capacitor (high K) and the first inductor 126 of the high pass filter 120 may not be as wide. Given the differences in between the high pass filter 120 and the low pass filter 140, each of these filters may be formed on different wafers during the fabrication process and then mated or coupled to the antenna 110 separately during the final fabrication of the diplexer circuit 100 or placement on a printed circuit board (not shown).

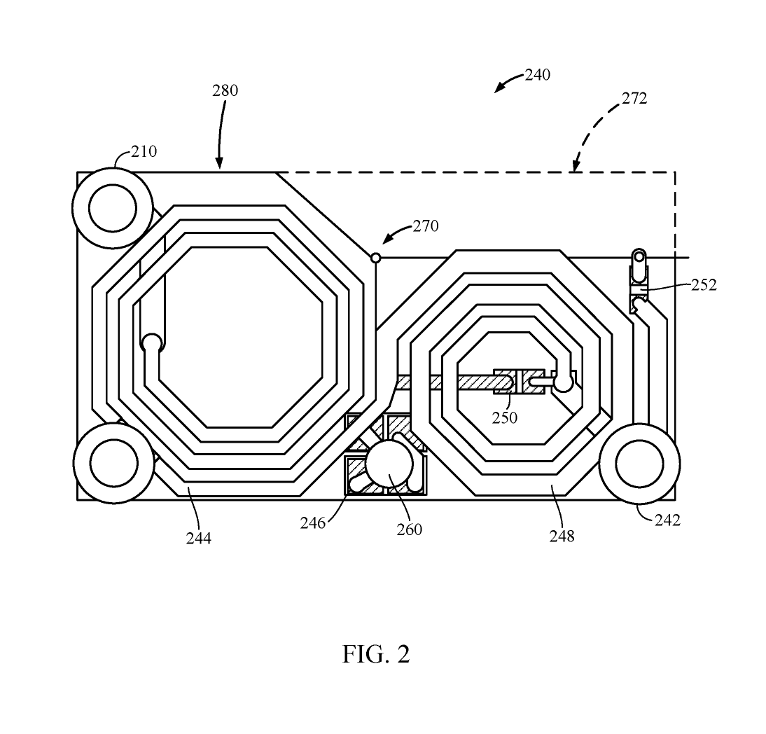

FIG. 2 illustrates an exemplary wafer with a low pass filter circuit in accordance with some examples of the disclosure. As shown in FIG. 2, a low pass filter circuit 240 (e.g., low pass filter 140) may include a substrate wafer 280 (e.g., a glass substrate wafer, organic substrate wafer, or a ceramic substrate wafer), an antenna 210 (e.g., antenna 110 or antenna port), a first inductor 244 (e.g., first inductor 144), a first capacitor 246 (e.g., first capacitor 146), a second inductor 248 (e.g., second inductor 148), a second capacitor 250 (e.g., second capacitor 150), a third capacitor 252 (e.g., third capacitor 152), an output 242 (e.g., output 142), and a ground 260 (e.g., ground 160). The substrate wafer 280 may include an obtuse angle 270 on the perimeter, such as approximately 120 degrees or 135 degrees for octagonal inductors. By using an obtuse angle on the perimeter instead of a rectangular substrate, an unused portion 272 of the substrate wafer 280 may be removed lessening the footprint of the substrate wafer 280. The first inductor 244 may be wider than the second inductor 248 and the obtuse angle 270 may be configured to follow the contour of the first inductor 244. The first inductor 244 and the second inductor 248 may be large value inductors so that thicker metal is desirable. The first capacitor 246, the second capacitor 250, and the third capacitor 252 may be large value capacitors so that thinner or higher K dielectric material may be desired for process control and reliability.

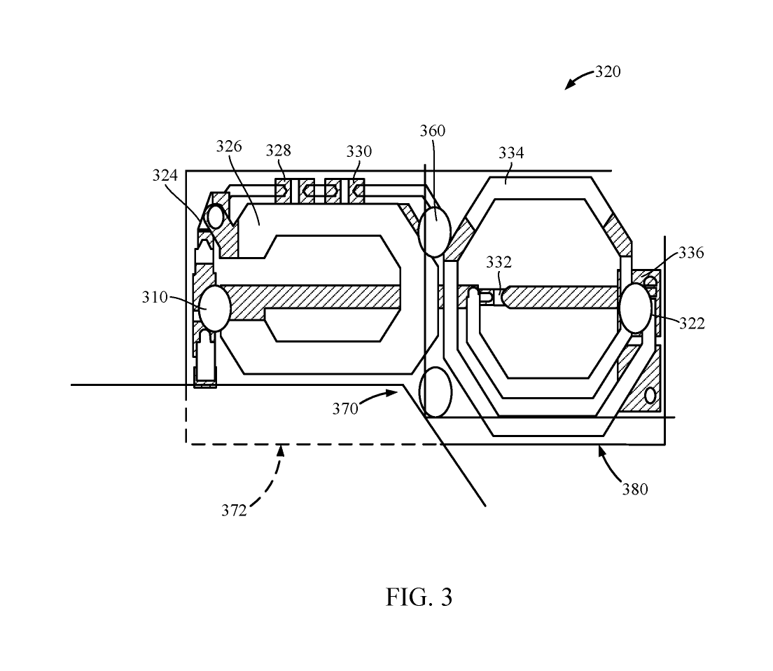

FIG. 3 illustrates an exemplary wafer with a high pass filter in accordance with some examples of the disclosure. As shown in FIG. 3, a high pass filter circuit 320 (e.g., high pass filter 120) may include a substrate wafer 380 (e.g., a glass substrate wafer, organic substrate wafer, or a ceramic substrate wafer), an antenna 310 (e.g., antenna 110 or antenna port), a first capacitor 324 (e.g., first capacitor 124), a first inductor 326 (e.g., first inductor 126), a second capacitor 328 (e.g., second capacitor 128), a third capacitor 330 (e.g., third capacitor 130), a second inductor 334 (e.g., second inductor 134), a fourth capacitor 332 (e.g., fourth capacitor 132), a fifth capacitor 336 (e.g., fifth capacitor 136), an output 322 (e.g., output 122), and a ground 360 (e.g., ground 160). The substrate wafer 380 may include an obtuse angle 370 on the perimeter, such as approximately 120 degrees or 135 degrees for octagonal inductors. By using an obtuse angle on the perimeter instead of a rectangular substrate, an unused portion 372 of the substrate wafer 380 may be removed lessening the footprint of the substrate wafer 380. The second inductor 334 may be wider than the first inductor 326 and the obtuse angle 370 may be configured to follow the contour of the second inductor 334. The first inductor 326 and the second inductor 334 may be small value inductors so that thinner metal is acceptable. The first capacitor 324, the second capacitor 328, the third capacitor 330, the fourth capacitor 332, and the fifth capacitor 336 may be small value capacitors so that thicker or lower K dielectric material may be desired for process control and reliability.

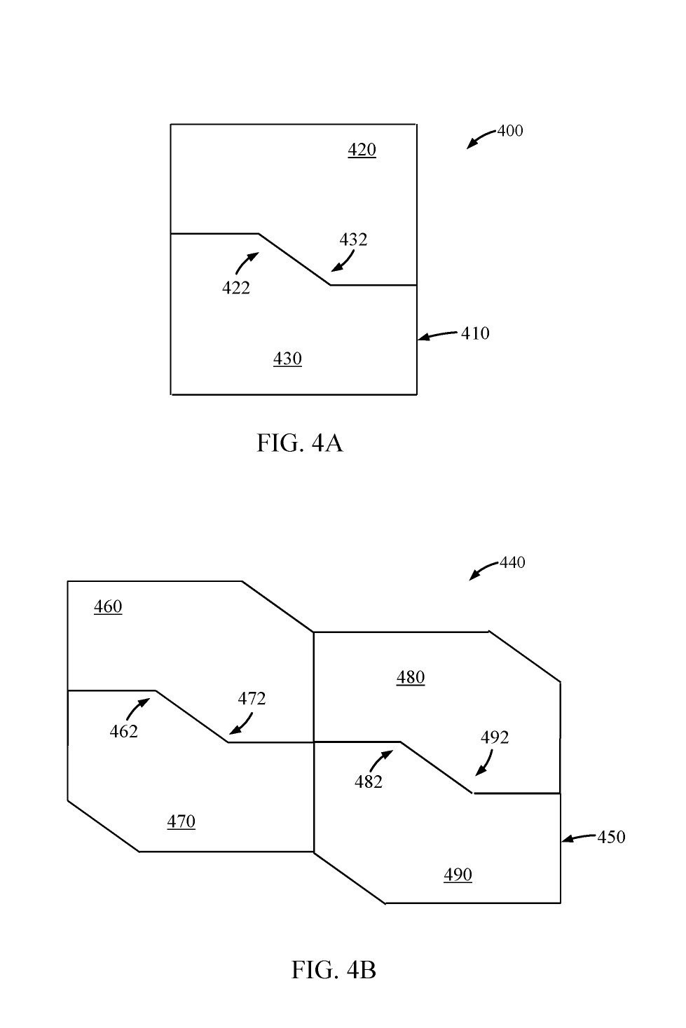

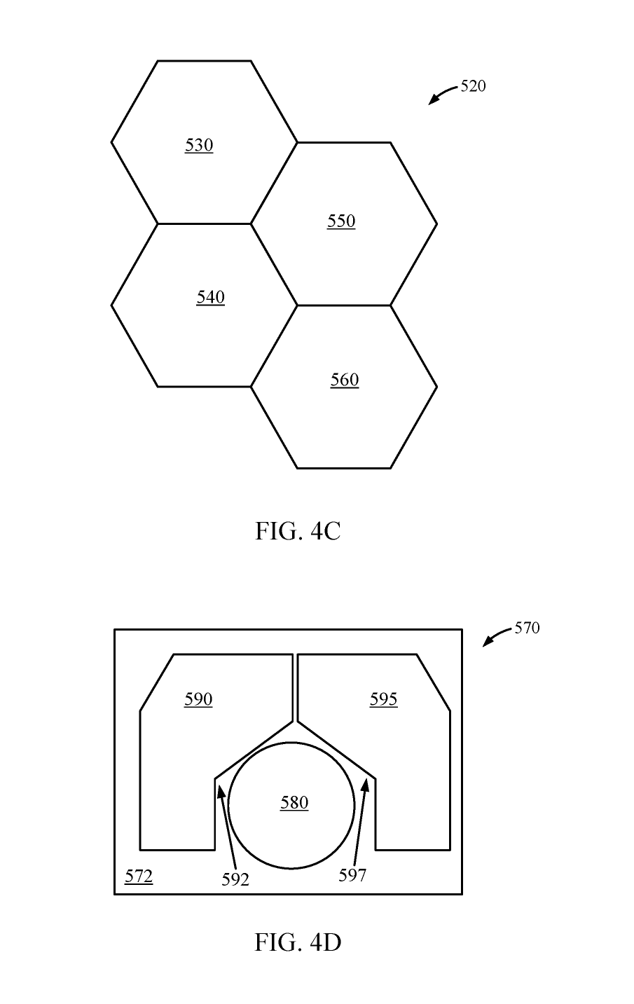

FIG. 4A illustrates two exemplary mated wafers in accordance with some examples of the disclosure. As shown in FIG. 4A, a package 400 may include a substrate wafer 410 (e.g., substrate wafer 280) with a first portion 420 and a second portion 430. The first portion 420 may include a first circuit (e.g., high pass filter 120 shown in FIG. 1), and the second portion 430 may include a second circuit (e.g., low pass filter 140 shown in FIG. 1). The first portion 420 may include a first obtuse angle 422 (e.g., obtuse angle 270 shown in FIG. 2) on a perimeter of the first portion 420 and the second portion 430 may include a second obtuse angle 432 (e.g., obtuse angle 370 shown in FIG. 3) on a perimeter of the second portion 430 such that the first portion 420 and the second portion 430 are configured to mate together to form an outer perimeter of the substrate wafer 410 that comprises right angles.

FIG. 4B illustrates four exemplary mated wafers in accordance with some examples of the disclosure. As shown in FIG. 4B, a package 440 may include a substrate wafer 450 (e.g., substrate wafer 280) with a first portion 460, a second portion 470, a third portion 480, and a fourth portion 490. The first portion 460 may include a first circuit (e.g., high pass filter 120 shown in FIG. 1), the second portion 470 may include a second circuit (e.g., low pass filter 140 shown in FIG. 1), the third portion 480 may include a third circuit (e.g., high pass filter 120 shown in FIG. 1), and the fourth portion 490 may include a fourth circuit (e.g., low pass filter 140 shown in FIG. 1). The first portion 460 may include a first obtuse angle 462 (e.g., obtuse angle 270 shown in FIG. 2) on a perimeter of the first portion 460, and the second portion 470 may include a second obtuse angle 472 (e.g., obtuse angle 370 shown in FIG. 3) on a perimeter of the second portion 470 such that the first portion 460 and the second portion 470 are configured to mate together. The third portion 480 may include a third obtuse angle 482 (e.g., obtuse angle 270 shown in FIG. 2) on a perimeter of the third portion 480, and the fourth portion 490 may include a fourth obtuse angle 492 (e.g., obtuse angle 370 shown in FIG. 3) on a perimeter of the fourth portion 490 such that the third portion 480 and the fourth portion 490 are configured to mate together.

FIG. 4C illustrates four exemplary mated wafers in accordance with some examples of the disclosure. As shown in FIG. 4C, a substrate wafer 520 (e.g., substrate wafer 280) may include a first portion 530, a second portion 540, a third portion 550, and a fourth portion 560. Each of the first portion 530, the second portion 540, the third portion 550, and the fourth portion 560 may include one or more passive components or circuits (not shown), such as a high pass filter 120 or a low pass filter 140. Each of the first portion 530, the second portion 540, the third portion 550, and the fourth portion 560 may include a plurality of obtuse angles on a respective perimeter to form hexagonal shapes, such that the individual portions mate with other portions as shown.

FIG. 4D illustrates two exemplary wafers and an antenna in accordance with some examples of the disclosure. As shown in FIG. 4D, a diplexer assembly 570 may include a first portion 590 with a first circuit 592 (e.g., first portion 420 with a high pass filter 120), a second portion 595 with a second circuit 597 (e.g., second portion 430 with a low pass filter 140), coupled to an antenna 580 (e.g., antenna 110) and mounted on a printed circuit board 572 such that the first portion 590 and the second portion 595 are configured to contour around the antenna 580 thereby conserving space on the printed circuit board 572 (i.e., smaller footprint on the printed circuit board 572) as well as providing shorter signal paths from the circuits 592, 597 to the antenna 580 versus conventional rectangular shaped portions.

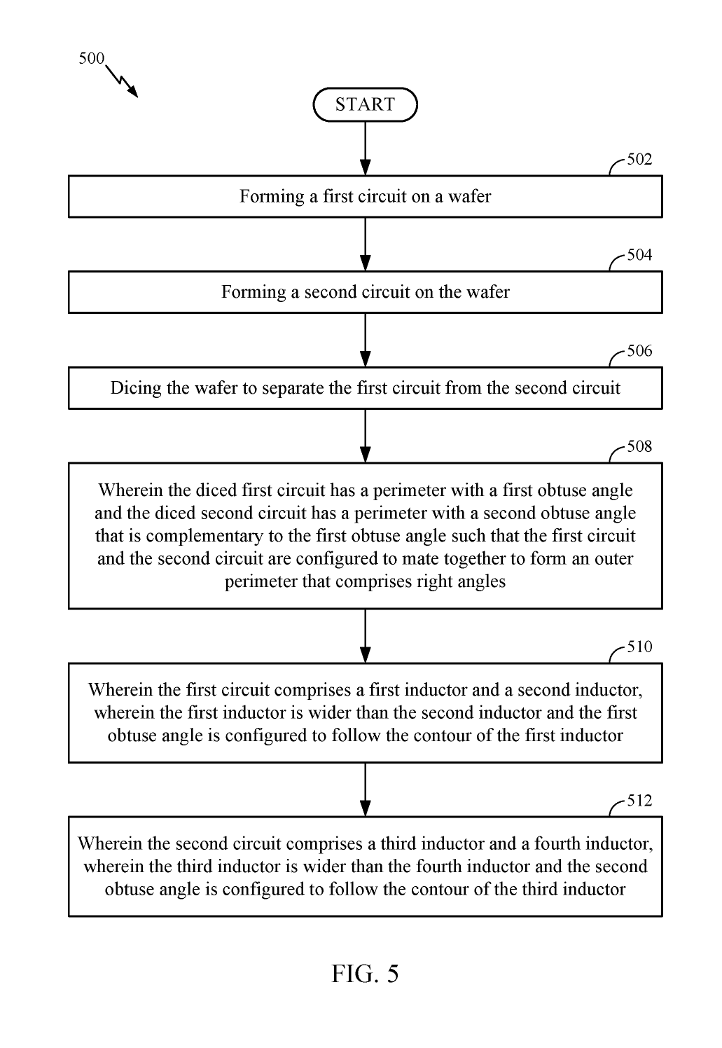

FIG. 5 illustrates an exemplary partial method for dicing a wafer in accordance with some examples of the disclosure. As shown in FIG. 5, the partial method 500 begins in block 502 with forming a first circuit (e.g., high pass filter 120) on a wafer (e.g., substrate wafer 280). The partial method 500 continues in block 504 with forming a second circuit (e.g., low pass filter 140) on the wafer. The partial method 500 continues in block 506 with dicing the wafer to separate the first circuit from the second circuit. The partial method 500 continues in block 508 wherein the diced first circuit has a perimeter with a first obtuse angle and the diced second circuit has a perimeter with a second obtuse angle that is complementary to the first obtuse angle such that the first circuit and the second circuit are configured to mate together to form an outer perimeter that comprises right angles. The partial method 500 may end or also continues in block 510 wherein the first circuit comprises a first inductor and a second inductor, wherein the first inductor is wider than the second inductor and the first obtuse angle is configured to follow the contour of the first inductor. The partial method 500 may end or also continues in block 512 wherein the second circuit comprises a third inductor and a fourth inductor, wherein the third inductor is wider than the fourth inductor and the second obtuse angle is configured to follow the contour of the third inductor.

It will be appreciated that various aspects disclosed herein can be described as functional equivalents to the structures, materials and/or devices described and/or recognized by those skilled in the art. For example, in one aspect, an apparatus may comprise a means for carrying a circuit or components (see, e.g., substrate wafer 280 in FIG. 2), a means for receiving and transmitting a signal (e.g., antenna 110 in FIG. 1), a first means for filtering a signal (see, e.g., high pass filter 120 in FIG. 1), a second means for filtering a signal (e.g., low pass filter 140 in FIG. 1), wherein the first means for filtering a signal is on a first portion of the means for carrying a circuit and the second means for filtering a signal is on a second portion of the means for carrying a circuit, and wherein the first portion has a first obtuse angle (e.g., obtuse angle 270 in FIG. 2) on a perimeter of the first portion and the second portion has a second obtuse angle (e.g., obtuse angle 370 in FIG. 3) on a perimeter of the second portion that is complementary to the first obtuse angle on the perimeter of the first portion and the first portion and the second portion are configured to mate together to form an outer perimeter that comprises right angles. It will be appreciated that the aforementioned aspects are merely provided as examples and the various aspects claimed are not limited to the specific references and/or illustrations cited as examples.

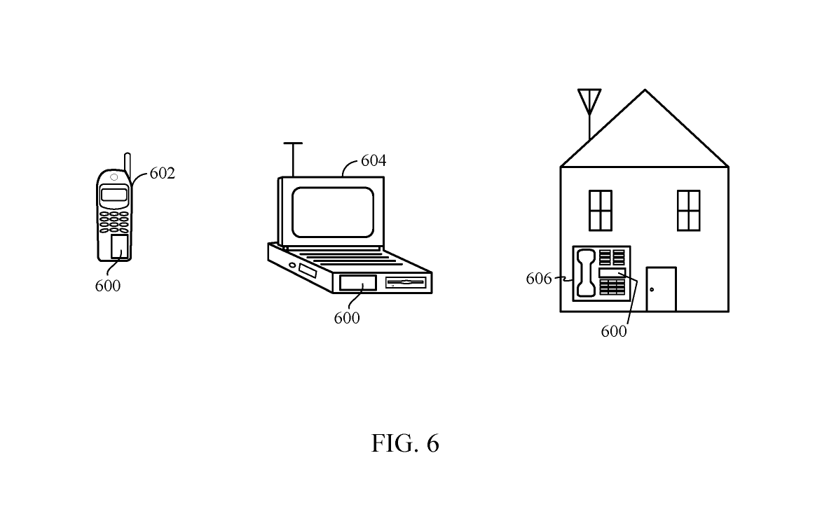

FIG. 6 illustrates various electronic devices that may be integrated with any of the aforementioned integrated device, semiconductor device, integrated circuit, die, interposer, package or package-on-package (PoP) in accordance with some examples of the disclosure. For example, a mobile phone device 602, a laptop computer device 604, and a fixed location terminal device 606 may include an integrated device 600 as described herein. The integrated device 600 may be, for example, any of the integrated circuits, dies, integrated devices, integrated device packages, integrated circuit devices, device packages, integrated circuit (IC) packages, package-on-package devices described herein. The devices 602, 604, 606 illustrated in FIG. 6 are merely exemplary. Other electronic devices may also feature the integrated device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

The exemplary wafers and packages shown and described herein may be used for a number of applications. For example, in a radio frequency (RF) filter (e.g., a high pass filter 120 or low pass filter 140) with at least one obtuse angle, the filter die has at least 5 sides (and may be 6 or 8 sides), the obtuse angle may be 135° aligned w/an octagonal inductor shape, the filter die substrate may be made of 1) glass, 2) organic, or 3) ceramic materials, and mechanical or laser dicing may be used to fabricate the filter die. In a RF multiplexer made of at least two obtuse angled dies, a multiplexer may consists of multiple filters (for example, diplexer (DPX)=low-pass filter (LPF)+high pass filter (HPF)), the LPF may use high value L (inductance) & C (capacitance) (due to f∝√LC), using thick (>10 um) & high-conductivity metal (Cu) for L and high capacitance density (>0.5 nF/mm2) dielectric material to achieve high-Q (Q=ωL/R (resistance) or 1/ωCR), the HPF may use low value L & C, to use thinner (<10 um) metal and/or lower-conductivity metal (Al) for L and low capacitance density (<0.5 nF/mm2) to optimize size/cost/performance & process tolerance (at higher f (frequency), f∝√LC become more sensitive to LC variation), and the two optimized LPF & HPF may be wrapped around an antenna port (usually circular) to minimize path loss & PCB footprint (See FIG. 4D, for example). In a RF module with at least one obtuse angle, the module may have at least 5 sides with an obtuse angle RF filter/multiplexer parts and may be fabricated using punch singulation thus allowing the RFFE module to wrap around the antenna port to minimize path loss & PCB footprint.

In this description, certain terminology is used to describe certain features. The term “mobile device” can describe, and is not limited to, a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). Further, the terms “user equipment” (UE), “mobile terminal,” “mobile device,” and “wireless device,” can be interchangeable.

One or more of the components, processes, features, and/or functions illustrated in FIGS. 1-6 may be rearranged and/or combined into a single component, process, feature or function or incorporated in several components, processes, or functions. Additional elements, components, processes, and/or functions may also be added without departing from the disclosure. It should also be noted that FIGS. 1-6 and its corresponding description in the present disclosure is not limited to dies and/or ICs. In some implementations, FIGS. 1-6 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE) or other protocols that may be used in a wireless communications network or a data communications network.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the situation is such that inventive content may reside in fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions of this method.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A glass substrate wafer comprising:
a first circuit on a first portion of a glass substrate;
a second circuit on a second portion of the glass substrate; and
wherein the first portion has a first obtuse angle on a perimeter of the first portion and the second portion has a second obtuse angle on a perimeter of the second portion that is complementary to the first obtuse angle on the perimeter of the first portion and the first portion and the second portion are configured to mate together to form an outer perimeter that comprises right angles.

2. The glass substrate wafer of claim 1, further comprising:
a first inductor on the first portion; and
a second inductor on the first portion, wherein the first inductor is wider than the second inductor and the first obtuse angle is configured to follow a contour of the first inductor.

3. The glass substrate wafer of claim 2, further comprising:
a third inductor on the second portion; and
a fourth inductor on the second portion, wherein the third inductor is wider than the fourth inductor and the second obtuse angle is configured to follow a contour of the third inductor.

4. The glass substrate wafer of claim 1, wherein the first circuit is a high pass filter and the second circuit is a low pass filter.

5. The glass substrate wafer of claim 1, wherein the first obtuse angle is approximately 135 degrees and the second obtuse angle is approximately 135 degrees.

6. The glass substrate wafer of claim 1, wherein the first circuit comprises a first inductor and a first capacitor in parallel.

7. The glass substrate wafer of claim 6, wherein the second circuit comprises a second inductor and a second capacitor in parallel.

8. The glass substrate wafer of claim 1, wherein the glass substrate wafer is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

9. A package comprising:
a passive-on-glass (POG) structure with a passive component; and
wherein the POG structure has a substrate that comprises an obtuse interior angle, a reflex interior angle, and a plurality of right angles.

10. The package of claim 9, wherein the substrate is one of a glass, organic, or ceramic substrate.

11. The package of claim 9, wherein the substrate has only one obtuse angle on the perimeter.

12. The package of claim 9, wherein the passive component comprises a first inductor and a second inductor, wherein the first inductor is wider than the second inductor and the obtuse interior angle is configured to follow a contour of the first inductor and the reflex interior angle is configured to follow a contour of the second inductor.

13. The package of claim 9, wherein the passive component is a high pass filter.

14. The package of claim 9, wherein the passive component is a low pass filter.

15. The package of claim 9, wherein the obtuse interior angle is approximately 135 degrees.

16. The package of claim 9, wherein the passive component comprises an inductor.

17. The package of claim 16, wherein the passive component comprises a capacitor in parallel with the inductor.

18. The package of claim 9, wherein the package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

19. A method of dicing a semiconductor wafer, comprising:
forming a first circuit on a wafer;
forming a second circuit on the wafer; and
dicing the wafer to separate the first circuit from the second circuit, wherein the diced first circuit has a perimeter with a first obtuse angle and the diced second circuit has a perimeter with a second obtuse angle that is complementary to the first obtuse angle such that the first circuit and the second circuit are configured to mate together to form an outer perimeter that comprises right angles.

20. The method of claim 19, wherein the first circuit comprises a first inductor and a second inductor, wherein the first inductor is wider than the second inductor and the first obtuse angle is configured to follow a contour of the first inductor.

21. The method of claim 20, wherein the second circuit comprises a third inductor and a fourth inductor, wherein the third inductor is wider than the fourth inductor and the second obtuse angle is configured to follow a contour of the third inductor.

22. A glass substrate wafer comprising:
a first circuit on a first portion of a glass substrate;
a second circuit on a second portion of the glass substrate; and
wherein the first portion has an obtuse angle on a perimeter of the first portion and the second portion has a reflex angle on a perimeter of the second portion that is complementary to the obtuse angle on the perimeter of the first portion.

23. The glass substrate wafer of claim 22, wherein the first circuit comprises a first modular component and the obtuse angle is configured to follow a contour of the first modular component.

24. The glass substrate wafer of claim 23, wherein the second circuit comprises a second modular component and the reflex angle is configured to follow a contour of the second modular component.

25. The glass substrate wafer of claim 22, wherein the first circuit is a high pass filter and the second circuit is a low pass filter.

26. The glass substrate wafer of claim 22, wherein the obtuse angle is approximately 135 degrees and the reflex angle is approximately 45 degrees.

27. The glass substrate wafer of claim 22, wherein the first circuit comprises a first inductor and a first capacitor in parallel.

28. The glass substrate wafer of claim 27, wherein the second circuit comprises a second inductor and a second capacitor in parallel.

29. The glass substrate wafer of claim 22, wherein the glass substrate wafer is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
